(19) United States
(12) Patent Application Publication
(10) Pub. No.: US 2021/0385983 A1
(43) Pub. Date: Dec. 9, 2021

(54) ELECTROMAGNETIC INTERFERENCE SHIELDS

(71) Applicant: Hewlett-Packard Development Company, L.P., Spring, TX (US)

(72) Inventors: Shih Huang Wu, Spring, TX (US); Kuan-Ting Wu, Taipei City (TW)

(73) Assignee: Hewlett-Packard Development Company, L.P., Spring, TX (US)

(21) Appl. No.: 17/286,543

(22) PCT Filed: Dec. 7, 2018
(86) PCT No.: PCT/US2018/064412

§ 371 Date: Apr. 19, 2021

(51) Int. Cl. H05K 9/00; B32B 5/02; B32B 27/12

(52) U.S. Cl. CPC H05K 9/0088; B32B 5/028; B32B 27/12; H05K 9/009; B32B 2307/202; B32B 2255/20; B32B 2255/10; B32B 2307/732; B32B 2250/03; B32B 2250/40; B32B 2307/212

(57) ABSTRACT

The present disclosure relates to an electromagnetic interference shield. The electromagnetic interference shield comprises a composite film that comprises a first carbon layer comprising an electrically conducting carbon material; a second carbon layer comprising an electrically conducting carbon material; and a porous layer between the first carbon layer and second carbon layer.

### BACKGROUND

The electronic components of electronic devices can generate heat and electromagnetic interference.

### BRIEF DESCRIPTION OF THE DRAWINGS

FIG. 1 is a schematic view of an example of a composite film according to the present disclosure.

FIG. 2 is a schematic view of another example of a composite film according to the present disclosure.

FIG. 3 illustrates a schematic flow chart for an example of a roll-to-roll process for the manufacture of a composite according to an example of the present disclosure.

FIG. 4 illustrates a schematic flow chart for another example of a roll-to-roll process for the manufacture of a composite according to another example of the present disclosure.

The figures depict several examples of the present disclosure. However, it should be understood that the present disclosure is not limited to the examples depicted in the figures.

### DETAILED DESCRIPTION

Before the present disclosure is described, it is to be understood that this disclosure is not limited to the particular process steps and materials disclosed herein because such process steps and materials may vary somewhat. It is also to be understood that the terminology used herein is used for the purpose of describing particular examples only. The terms are not intended to be limiting because the scope of the present disclosure is intended to be limited only by the appended claims and equivalents thereof.

For clarity of the description, the drawings are not drawn to a uniform scale. In particular, vertical scales may differ and may vary from one drawing to another. Additionally, directional terminology, such as “top”, “bottom”, etc., is used with reference to the orientation of the figure(s) being described. The components of the disclosure can be positioned in a number of different combinations, therefore the directional terminology is used for purposes of illustration and is in no way limiting.

It is noted that, as used in this specification and the appended claims, the singular forms “a,” “an,” and “the” include plural referents unless the context clearly dictates otherwise.

As used in this disclosure, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

A polymer may be described as comprising a certain weight percentage of monomer. This weight percentage is indicative of the repeating units formed from that monomer in the polymer.

As used in this disclosure, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a numerical range of “about 1 wt % to about 5 wt %” should be interpreted to include not only the explicitly recited values of about 1 wt % to about 5 wt %, but also include individual values and sub-ranges within the indicated range. Thus, included in this numerical range are individual values such as 2, 3.5, and 4 and sub-ranges such as from 1 to 3, from 2 to 4, and from 3 to 5, etc.

This same principle applies to ranges reciting only one numerical value. Furthermore, such an interpretation should apply regardless of the breadth of the range or the characteristics being described.

The electronic components of electronic devices can generate electromagnetic interference. This may affect the performance of the electronic device, as well as other electronic devices that may operating within interference range. The electronic components of electronic devices can also generate heat. High temperatures within an electronic device can also affect the device's battery life, and the heat generated by electronic components can generate hot spots within the device. For example, in a laptop computer, heat-generating components may be located beneath a touch screen or beneath the “palm rest” of a keyboard, where a user's wrists may rest when typing. The heat generated by these components can be transferred through the laptop screen or housing, causing the user discomfort or sometimes pain. Likewise, heat-generating components may heat a laptop housing to an elevated temperature, such that a user may experience discomfort if working with the laptop on his or her lap.

Graphite can be used to dissipate heat and reduce the likelihood of hot spot formation battery life. For example, a layer of graphite may be positioned adjacent a source of heat to dissipate heat away from the source. As graphite is an electrical conductor, graphite can also act as an electromagnetic interference shield. The graphite layer may reduce the rate at which electromagnetic interference is transmitted to surrounding areas.

The present disclosure relates to an electromagnetic interference shield. The electromagnetic interference shield comprises a composite film that comprises a first carbon layer comprising an electrically conducting carbon material; a second carbon layer comprising an electrically conducting carbon material; and a porous layer between the first carbon layer and second carbon layer.

The electromagnetic interference shield of the present disclosure may be positioned adjacent a source of heat in an electronic device. Heat from the heat source may be dissipated by the composite film, for example, by conduction and/or radiation. For example, where the composite film is positioned such that the first carbon layer is closer to the heat source, heat may be conducted away from the heat source. In some examples, the heat may be transferred e.g. laterally in an in-plane direction across the first carbon layer and dissipated across the surface of the first carbon layer. In some examples, the heat may also be transferred along a temperature gradient to the second carbon layer through the porous layer (e.g. through-plane direction). Heat may then be dissipated from the second carbon layer to the surroundings by, for example, conduction and/or radiation.

It has been found that, by positioning a porous layer between the first carbon layer and the second carbon layer, the rate at which heat is transferred between the carbon layers can be reduced. For example, the porous layer may act as an insulator that may reduce the rate of heat transfer to the second carbon layer. By reducing the rate at which heat is transferred between the first carbon layer and the second carbon layer, the surface temperature of the second carbon layer may be reduced. Thus, components (e.g. screen or housing of electronic device) adjacent the second carbon layer may be less hot to the touch, reducing the risk of a user's discomfort or injury. The risk of hotspot formation may also be reduced.

In some examples, the porous layer may be a mesh layer. The mesh layer may comprise a polymer mesh.

In some examples, the mesh layer comprises a mesh material selected from polyimide, polyurethane, polyacrylic, polyester and polycarbonate, or a combination thereof.

In some examples, the thickness of the mesh layer is between about 30 μm and about 500 μm.

In some examples, the electrically conducting carbon material of the first carbon layer and/or the second carbon layer comprises at least one of carbon black, carbon nanotubes, graphite and graphene.

In some examples, the electrically conducting carbon material comprises graphite.

In some examples, the composite film further comprises at least one electrically conducing polymer layer.

In some examples, the at least one electrically conducting polymer layer is positioned between the first carbon layer and second carbon layer.

In some examples, the composite film comprises a first electrically conducting polymer layer and a second electrically conducting polymer layer between the first carbon layer and the second carbon layer; wherein the porous layer is positioned between the first electrically conducting polymer layer and second electrically conducting polymer layer.

In some examples, the electrically conducting polymer layer comprises at least one of poly-3,4-ethylenedioxythiophene (PEDOT), polyacetylene, poly(p-phenylene vinylene), poly(thienylene vinylene), polythiophene, poly-3-alkylthiophene, polypyrrole, polyaniline and polyphenylene.

In some examples, the electrically conducting polymer further comprises at least one of polyurethane, polyester and/or urethane acrylate resin.

In some examples, the thickness of each of the first and second carbon layers is between about 5 and about 50 μm.

In some examples, the thickness of the composite film is between about 0.1 mm and about 0.5 mm.

In some examples, the first carbon layer and/or the second carbon layer comprises graphite.

In some examples, the graphite is deposited on a polymer film.

In some examples, the polymer film is a polyethylene terephthalate polymer film.

The present disclosure also relates to an electronic device comprising an electromagnetic interference shield comprising a composite film that comprises: a first carbon layer; a second carbon layer; and a porous layer between the first carbon layer and second carbon layer.

The electromagnetic interference shield may be positioned adjacent a central processing unit, a printed circuit board, and/or a graphics processing unit of the device.

### Carbon Layers

The first and second carbon layers may comprise any suitable electrically conducting carbon material. Examples of suitable electrically conducting carbon materials include graphite, graphene, carbon nanotubes and carbon black. In some examples, the electrically conducting carbon material comprises graphitic carbon. In some examples, the electrically conducting carbon material comprises carbon nanotubes, graphite and/or graphene. In some examples, the electrically conducting carbon material comprises graphite and/or graphene. In some examples, the electrically conducting carbon material comprises graphite. The electrically conducting carbon material in the first carbon layer may be the same or different from the electrically conducting carbon material in the second carbon layer. In some examples, the electrically conducting carbon material has an anisotropic thermal conductivity profile.

In some examples, the thickness of each of the first and second carbon layers is between about 5 and about 60 μm. In some examples, the thickness of each of the first and second carbon layers is between about 6 and about 50 μm, for example, between about 10 and about 45 μm or between about 20 and about 40 μm. The first carbon layer may have substantially the same thickness to the second carbon layer. In some examples, the first carbon layer may have a different thickness from the second carbon layer.

In some examples, the electrically conducting carbon material may be applied onto a polymer film. The electrically conducting carbon material may be applied onto a polymer film using any suitable method. Examples include deposition, coating (e.g. roll-to-roll coating) or using an adhesive. In one example, the electrically conducting carbon material may be dispersed in a resin and the resulting mixture applied onto a polymer film. Thus, the first carbon layer and/or the second carbon layer may comprise a polymer layer comprising particles of the electrically conducting carbon material in a resin matrix, wherein the polymer layer is deposited on a polymer film.

The polymer layer may have a thickness of about 6 and about 50 μm, for example, between about 10 and about 45 μm or between about 20 and about 40 μm. The resin may be formed of any suitable resin, for example, a polyurethane resin, polyacrylic, and polyester.

The polymer film may be any suitable film. Examples include polyester film, for instance, biaxially-oriented polyethylene terephthalate (Bo-PET) film. The polymer film may have a thickness of between about 5 μm and about 15 μm. In some examples, the polyester film may comprise a thickness of between about 8 to 10 μm.

The particles of the electrically conducting carbon material may be selected from particles of graphite, graphene, carbon nanotubes and carbon black. In some examples, the particles of the electrically conducting carbon material may be graphite particles. The particles of the electrically conducting carbon material may form about 0.05 to about 10 weight %, for example, about 0.1 to about 7 weight % or about 0.1 to about 5 weight % of the polymer layer. In some examples, the particles may form about 0.1 to about 3 weight % of the polymer layer.

In some examples, the first carbon layer and/or the second carbon layer comprises a layer of the electrically conducting carbon material. In some examples, the first carbon layer and/or the second carbon layer consists essentially of a layer of the electrically conducting carbon material. The electrically conducting carbon material may be compressed or compacted in the presence or absence of a binder to form the first carbon layer and/or second carbon layer. In one example, the first carbon layer and/or the second carbon layer comprises a layer of graphite. The graphite may be compressed or compacted to form a sheet. In some examples, synthetic graphite may be used. In some examples, the first carbon layer and/or the second carbon layer may comprise a compressed or compacted graphite sheet having a thickness of about 5 and about 60 μm. In some examples, the thickness of the compressed or compacted graphite sheet may be between about 6 and about 50 μm, for example, between about 10 and about 45 μm or between about 20 and about 40 μm.

The first and second carbon layers may each have an in-plane thermal conductivity of about 400 to about 2300 W/mK, for example, about 600 to about 1,800 W/mK, for example,

The first and second carbon layers may each have a through-plane thermal conductivity of about 5 to about 100 W/mK, for example, about 8 to about 20 W/mK.

The first and second carbon layers may have a thermal conductivity that is greater in an in-plane direction than in a through-plane direction. Thus, the layers may have an anisotropic thermal conductivity profile. By having a high thermal conductivity in the in-plane direction, heat may be conducted away from a heat source laterally, allowing heat to be dissipated to the surroundings across a greater surface area. By having a lower thermal conductivity in the through-plane direction, the transfer of heat through the composite film may be reduced.

The first and second carbon layers may absorb electromagnetic interference at frequencies of about 3 KHz and about 300 GHz. For example, the first and second carbon layers may absorb electromagnetic interference in the radio frequency range.

The first and second carbon layers may be flexible. Thus, they may have the flexibility to conform to contours within an electronic device.

### Porous Layer

As mentioned above, a porous layer is positioned between the first carbon layer and the second carbon layer. As explained above, the porous layer may reduce the rate at which the heat is transferred between the carbon layers. Thus, although heat may be transmitted through the composite film from the carbon layer closer the heat source to the carbon layer further away from the heat source, by reducing the rate of heat transfer between the carbon layers, the temperature of the carbon layer remote from the heat source may be reduced. This can reduce the risk of hotspots and/or components near the remote carbon layer from overheating.

The porous layer may comprise a porous polymeric layer. The porous layer may comprise a mesh layer. The mesh layer may take the form of a woven web. Alternatively, the mesh may be a perforated film.

In some examples, the porous layer may comprise a polymeric mesh layer. In some examples, the porous layer may comprise a perforated or porous polymeric film.

The porous layer may perform an insulating function as a result of air contained within the porous layer. Air may be contained within pores of the porous layer, or within chambers defined by the porous layer and adjacent layers positioned on either side of the porous layer.

On average (e.g. mean), the openings may measure about 10 μm to about 70 μm across, for example, from about 20 μm to about 60 μm or from about 30 μm to about 50 μm across. In some examples, each of the openings may measure about 10 μm to about 70 μm across, for example, from about 20 μm to about 60 μm or from about 30 μm to about 50 μm across.

Where the porous layer comprises a polymeric material, the material may be selected from at least one of polyimide, polyurethane, polyacrylic, polyester and polycarbonate. In some examples, a polyimide may be used. In some examples, the porous layer may comprise a polymeric mesh, wherein the polymeric mesh is formed from at least one of polyimide, polyurethane, polyacrylic, polyester and polycarbonate. In some examples, a polyimide may be used. In some examples, the porous layer may comprise a perforated/porous polymer film, wherein the perforated/porous polymer film is formed from at least one of polyimide, polyurethane, polyacrylic, polyester and polycarbonate. In some examples, a polyimide may be used.

The porous layer may have a thickness of between about 30 μm and about 500 μm. In some examples, the porous layer can be between about 50 μm and about 450 μm. In some examples, the porous layer can be between about 70 μm and about 400 μm. In some examples, the porous layer can be between about 100 μm and 350 μm.

The thickness of the porous layer may be varied to achieve a balance between the rate of heat dissipation and the rate of heat transfer between the first carbon layer and the second carbon layer. Similarly, the porosity of the porous layer may be varied to achieve a balance between the rate of heat dissipation from the heat source and the rate of heat transfer between the first carbon layer and the second carbon layer. Additionally or alternatively, the material used to form the porous layer may be varied to achieve a balance between the rate of heat dissipation from the heat source and the rate of heat transfer between the first carbon layer and the second carbon layer.

The porosity of the porous layer may be at least about 40% by volume, for example, at least about 50% by volume. In some examples, the porosity may be about 60 to about 98% by volume, for example, about 70 to about 90% by volume.

The porous layer (e.g. mesh layer) may have low thermal conductivity. For example, the thermal conductivity through the mesh layer (e.g. in an in-plane and/or through-plane direction) may be about less than 5 W/mK, for example, less than about 3 W/mK, for example, less than about 1 W/mK. In some examples, the thermal conductivity of the porous layer (e.g. mesh layer) may be about 0.01 to about 1 W/mK, for example, 0.02-0.5 W/mK.

### Additional Layer(s)

The composite film may further comprise layer(s) in addition to the carbon layers and porous layer. In some examples, the composite film may comprise a polymer layer positioned between the first carbon layer and the second carbon layer. In some examples, this additional polymer layer may be adjacent the porous layer. In some examples, the composite film may comprise a polymer layer positioned on either side of the porous layer. Each of these polymer layers may also be positioned between the first carbon layer and the second carbon layer.

The polymer layer(s) may be electrically conducting polymer layer(s). In some example, the composite film comprises at least one electrically conducting polymer layer. The at least one electrically conducting polymer layer may be positioned between the first carbon layer and second carbon layer. In some examples, the composite film comprises a first electrically conducting polymer layer and a second electrically conducting polymer layer between the first carbon layer and the second carbon layer; wherein the porous layer is positioned between the first electrically conducting polymer layer and second electrically conducting polymer layer.

Where an electrically conducting polymer layer(s) is used, the electrically conducting polymer layer may absorb electromagnetic interference. Together with the first carbon layer and the second carbon layer, therefore, the electrically conducting polymer layer(s) may enhance the electromagnetic shield properties of the composite film.

The electrically conducting polymer layer may comprise an electrically conducting polymer. Any suitable electrically conducting polymer may be used. Examples include at least one of poly-3,4-ethylenedioxythiophene (PEDOT), polyacetylene, poly(p-phenylene vinylene), poly(thienylene vinylene), polythiophene, poly-3-alkylthiophene, polypyrrole, polyaniline and polyphenylene.

In some examples, the thickness of each electrically conducting polymer layer can be between about 10 μm and about 30 μm. In some examples, the thickness can be between about 15 μm and about 25 μm. In some examples, the thickness can be about 20 μm.

Where the first carbon layer and/or the second carbon layer comprises a polymer film supporting the electrically conducting carbon material (e.g. graphite), any electrically conducting polymer layer may be applied either to the polymer face or carbon face of the carbon layer. In some examples, the electrically conducting polymer layer may be applied to the polymer face.

In some examples, the composite film further comprises at least one adhesive layer. The adhesive layer may overly the first carbon layer or the second carbon layer, for example, to adhere or fix the composite film to part of an electronic device. Suitable adhesive polymers may be selected from at least one of epoxy, cyanoacrylates, urethane and acrylic adhesives.

In some examples, the thickness of the adhesive layer may be between about 10 μm and about 30 μm. In some examples, the thickness of the adhesive layer may be about 15 μm to about 25 μm.

In some examples, the adhesive layer may form the outermost layer of the composite film.

### Composite Film

The composite film of the present disclosure is or may form part of an electromagnetic interference shield. In some examples, the composite film is the electromagnetic interference shield such that the terms “electromagnetic interference shield” and “composite film” may be used interchangeably.

The electromagnetic interference shield may be positioned within an electronic device, for example, to absorb or reduce the amount of electromagnetic interference generated by the device and/or its components. The composite film may also help to dissipate heat from any sources of heat within the electronic device. By dissipating heat, the composite film may help to reduce the risk of hotspot formation, and/or reduce the risk of at least part of the electronic device from over-heating. For example, by positioning the composite film between a source of heat and part of the housing or screen of an electronic device, the composite film can reduce the risk of the housing or screen from becoming too hot to touch without discomfort or injury. The composite film may also reduce the risk of hotspot formation in the housing or screen of the electronic device.

The composite film may be flexible and capable of conforming to surfaces having different shapes and surface features.

The composite film may have a thickness of between about 0.1 mm and about 0.5 mm, for example, about 0.2 mm to about 0.4 mm, or about 0.3 mm. The length and the width of the composite film may be dependent, for example, on the size of the heat source and/or on the electronic device in which the composite film is to be positioned.

In some examples, the composite film can operate within an electronic device in the temperature ranges of between about 25 degrees C. and about 300 degrees C., for example, about 25 degrees C. and about 120 degrees C.

The location of the composite film in the selected electronic device may be in close contact, or in direct contact with the heat source. In some examples, the composite film may be situated to face a central processing unit, a printed circuit board, a graphics processing unit or any other source of heat. In some examples, only one face of the composite film directly faces the heat source within the electronic device.

The composite film may at least partially absorb or at least partially shield electromagnetic interference of a range of frequencies. For example, the composite film may shield radio frequencies in the range of between about 3 KHz and about 300 GHz.

To further illustrate the present disclosure, reference is made to the accompanying drawings. It is to be understood that the drawings illustrate examples that are not to be construed as limiting the scope of the present disclosure.

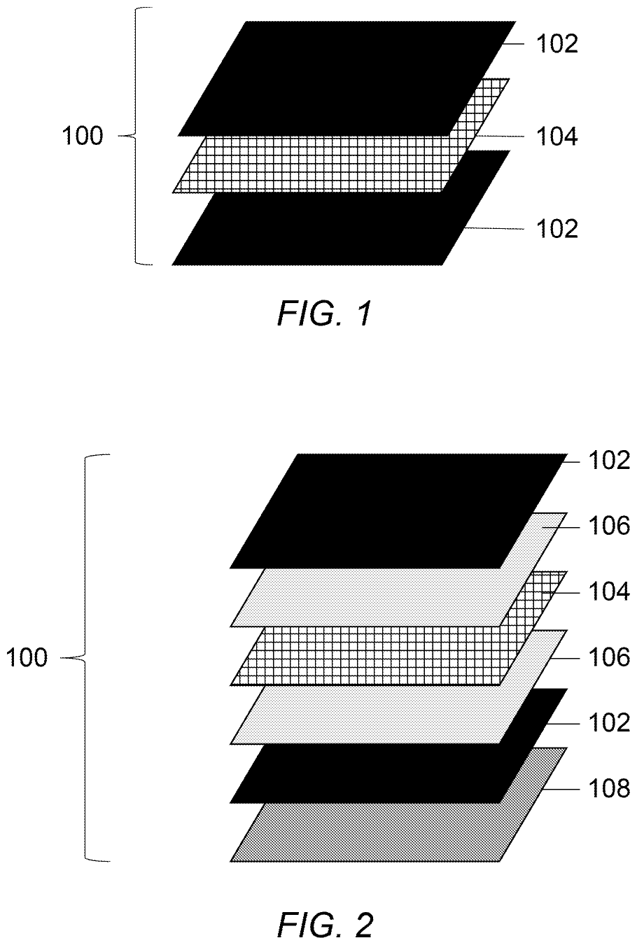

An example of the composite film of the present disclosure is shown in FIG. 1. This figure shows a schematic view of a composite film 100 for an electronic device. The film comprises first and second carbon layers 102, each comprising electrically conductive carbon material. For example, the electrically conductive carbon material may be graphite, such that the first and second carbon layers and first and second graphite layers, respectively.

Positioned between the first carbon layer and second carbon layer is a porous layer 104. The porous layer 104 may be a mesh layer comprising a polyimide polymer. The mesh layer may be formed by perforating a polyimide film.

In use, the composite film 100 of FIG. 1 may be positioned adjacent a source of heat in an electronic device. For example, the composite film 100 may be positioned over a CPU in e.g. a laptop. The composite film 100 may be positioned such that the first carbon layer is adjacent the CPU. Heat from the CPU may be dissipated away from the CPU as a result of the thermally conductive properties of the first carbon layer. The heat may be conducted laterally across the first carbon layer in an in-plane direction, allowing the heat to be dissipated across the surface area of the first carbon layer. Some heat may also be transmitted to the second carbon layer through the porous layer. However, the porous layer contains air (e.g. air may be contained in chambers defined by the first and second carbon layers and intervening mesh layer). Thus, the porous layer can act as an insulator, and the risk of components (e.g. screen or housing of electronic device) adjacent the second carbon layer from being e.g. too hot to touch is reduced.

The electrically conductive properties of the first carbon layer and second carbon layer also help to block the transmission of electromagnetic interference through the composite film 100.

A further example of the composite film of the present disclosure is shown in FIG. 2. This example is similar to the example shown in FIG. 1 and like numerals have been used to denote like components. Unlike the composite film of FIG. 1, the composite film 100 of FIG. 2 additionally includes an adhesive layer 108. The adhesive layer may help to affix the composite film in position within an electronic device.

Electrically conductive polymer layers 106 are also present on either side of the porous layer 14. The electrically conductive polymer layer may comprise an electrically conductive polymer. Examples include poly-3,4-ethylenedioxythiophene (PEDOT), polyacetylene, poly(p-phenylene vinylene), poly(thienylene vinylene), polythiophene, poly-3-alkylthiophene, polypyrrole, polyaniline and polyphenylene. The electrically conducting properties of the electrically conductive polymer layers 106 help the composite film 100 to act as a shield to stop or reduce the propagation of electromagnetic interference.

The present disclosure provides a method of manufacturing a composite film as described herein. The method may comprise positioning a porous layer between the first carbon layer and the second carbon layer. The layers may be pressed or joined together to form a composite film. In some examples, an electrically conducting polymer layer(s) may also be included in the composite film.

In some examples, the composite film may be formed by roll-to-roll processing. In roll-to-roll processing a web of, for example, the first carbon layer; a web of the second carbon layer and a web of the porous layer may be laminated by a roll-to-roll process to form a composite film. The process may be substantially continuous.

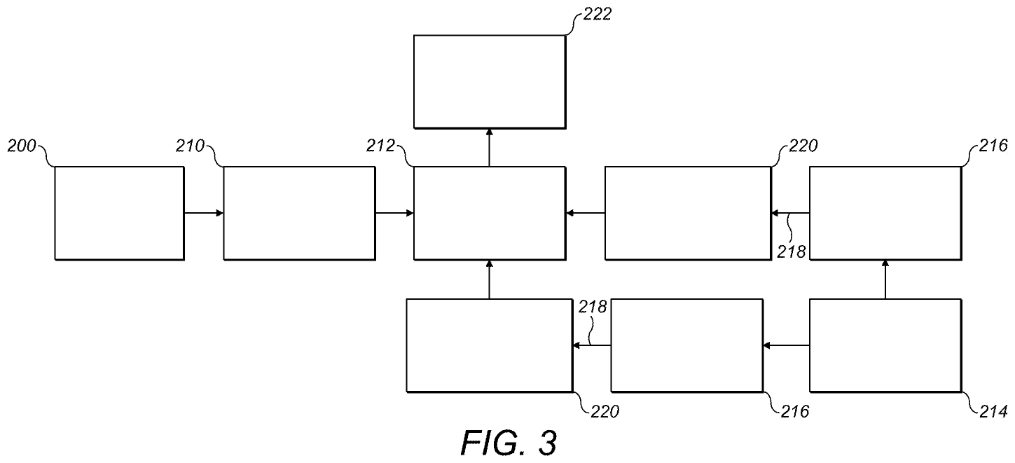

FIG. 3 illustrates a schematic flow chart for an example of a roll-to-roll process for manufacture of a composite according to an example of the present disclosure. In the process, a polymer film, for example, a polyimide film 200 may be perforated using e.g. an “embossing” roller 210 in a roll-to-roll process. The embossing roller comprises protrusions, which perforate the polyimide film. The resulting film is a polyimide mesh that is fed, to a roll-to-roll laminator 212.

A polymer film, for example, a polyester film 214 may be coated with a mixture of graphite and resin by roll-to-roll processing 216, 216 to form first and second webs of graphite-coated polymer 218. An electrically conducting polymer 220 may then be applied to (e.g. the polymer face of) the graphite-coated webs using a roll-to-roll process. The resulting webs are then fed to the laminator 212 for lamination on either side of the polyimide mesh.

The resulting laminate may be coated with an adhesive layer 222.

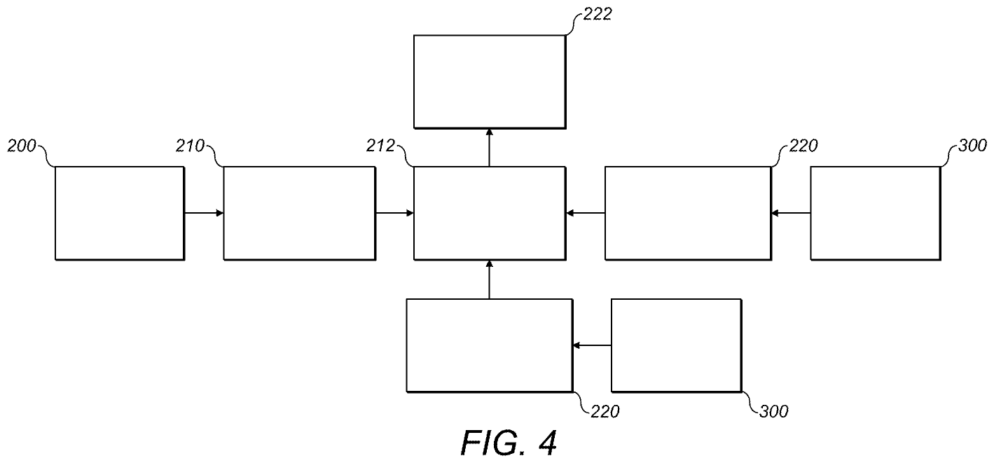

FIG. 4 is a schematic flow chart for another example of a roll-to-roll process for manufacture of a composite according to another example of the present disclosure. The flow chart is similar to that shown in FIG. 3 and like parts have been labelled with like numerals. However, rather than coating a polyester film 214 to form webs 218 of graphite-coated polymer, the electrically conducting polymer is applied to pre-formed synthetic graphite films 300.

1. An electromagnetic interference shield comprising a composite film that comprises:
a first carbon layer comprising an electrically conducting carbon material;
a second carbon layer comprising an electrically conducting carbon material; and
a porous layer between the first carbon layer and second carbon layer.

2. The shield according to claim 1, wherein the porous layer is a mesh layer.

3. The shield according to claim 1, wherein the electrically conducting carbon material of the first carbon layer and/or the second carbon layer comprises at least one of carbon black, carbon nanotubes, graphite and graphene.

4. The shield according to claim 3, wherein the electrically conducting carbon material comprises graphite.

5. The shield according to claim 4, wherein the graphite is deposited on a polymer film.

6. The shield according to claim 1, wherein the composite film further comprises at least one electrically conducing polymer layer.

7. The shield according to claim 6, wherein the at least one electrically conducting polymer layer is positioned between the first carbon layer and second carbon layer.

8. The shield according to claim 6, which comprises a first electrically conducting polymer layer and a second electrically conducting polymer layer between the first carbon layer and the second carbon layer; wherein the porous layer is positioned between the first electrically conducting polymer layer and second electrically conducting polymer layer.

9. The shield according to claim 6, wherein the electrically conducting polymer layer comprises at least one of poly-3,4-ethylenedioxythiophene (PEDOT), polyacetylene, poly(p-phenylene vinylene), poly(thienylene vinylene), polythiophene, poly-3-alkylthiophene, polypyrrole, polyaniline and polyphenylene.

10. The shield according to claim 9, wherein the electrically conducting polymer further comprises at least one of polyurethane, polyester and/or urethane acrylate resin.

11. The shield according to claim 2, wherein the mesh layer comprises a mesh material selected from polyimide, polyurethane, polyacrylic, polyester and polycarbonate, or a combination thereof.

12. The shield according to claim 2, wherein the thickness of the mesh layer is between about 30 μm and about 500 μm.

13. The shield according to claim 1, wherein the thickness of each of the first carbon layer and second carbon layer is between about 5 and about 50 μm.

14. The shield according to claim 1, wherein the thickness of the composite film is between about 0.1 mm and about 0.5 mm.

15. An electronic device comprising an electromagnetic interference shield comprising a composite film that comprises:
a first carbon layer;
a second carbon layer; and
a porous layer between the first carbon layer and second carbon layer.
